(19) United States
(12) Patent Application Publication
(10) Pub. No.: US 2025/0044369 A1
(43) Pub. Date: Feb. 6, 2025

(54) OUTLIER DIAGNOSIS METHOD FOR SERIES-CONNECTED CELLS

(71) Applicant: TAIWAN TRUEWIN TECHNOLOGY CO., LTD., Hsinchu City (TW)

(72) Inventor: Yu-Chen HSIEH, Hsinchu City (TW)

(21) Appl. No.: 18/362,303

(22) Filed: Jul. 31, 2023

(51) Int. Cl. G01R 31/396; G01R 31/3842; H02J 7/00

(52) U.S. Cl. CPC G01R 31/396; G01R 31/3842; H02J 7/0048; G01R 31/378

(57) ABSTRACT

The invention discloses an outlier diagnosis method for a series-connected lithium battery cells, the average voltage changes at the initial stage of discharge Vx and the average voltage changes at the end of charge Vy are detected and calculated for each cell, then an outlier index and z-score are calculated, and the z-score is used to screen the cell outliers that need pay attention.

### BACKGROUND

### Technical Field

The present invention relates to a method for diagnosing outliers in series-connected cells, especially relates to a method for automatically analyzing and detecting outliers in series-connected lithium batteries.

### Description of Related Art

The traditional art relies on manually interpreting parameters data or characteristic graphics of individual cells and then pick up outlier cells. It is a time-consuming process.

### SUMMARY OF THE INVENTION

An automatic outlier analysis is conceived for series-connected Li-Ion battery cells according to the present invention. Various parameters are automatically detected and collected, and then automatic analyzing to output a list of outlier cells that need to pay attention.

### BRIEF DESCRIPTION OF THE DRAWINGS

FIG. 1 shows a flow chart according to the present invention.

FIG. 2 shows a calculation of the average voltage change at the initial stage of discharge according to the present invention.

FIG. 3 shows a calculation of the average voltage change at the end of charge according to the present invention.

FIG. 4 shows a calculation of outlier index and z-score for each cell according to the present invention.

### DETAILED DESCRIPTION OF THE INVENTION

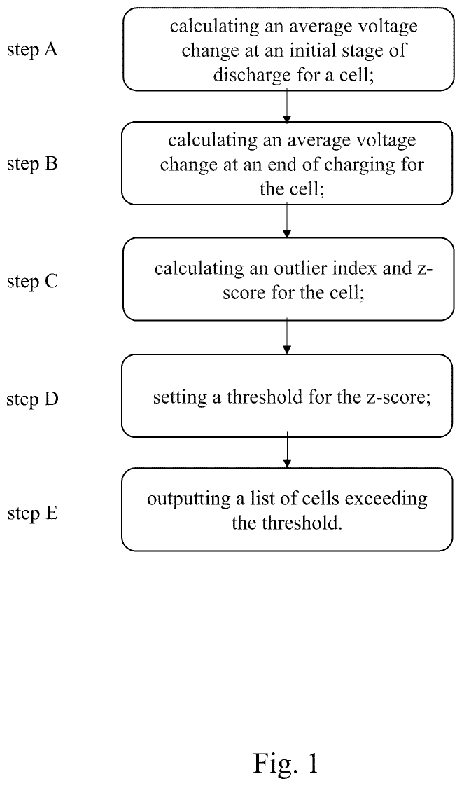

FIG. 1 shows a flow chart according to the present invention.

The present invention comprises the following steps:
Step A: calculating an average voltage change at an initial stage of discharge for a cell;
Step B: calculating an average voltage change at an end of charging for the cell;
Step C: calculating an outlier index and z-score for the cell;
Step D: setting a threshold for the z-score; and
Step E: outputting a list of cells exceeding the threshold.

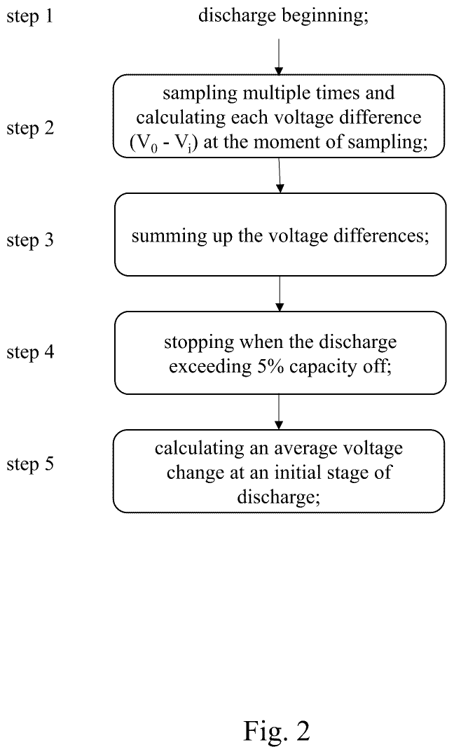

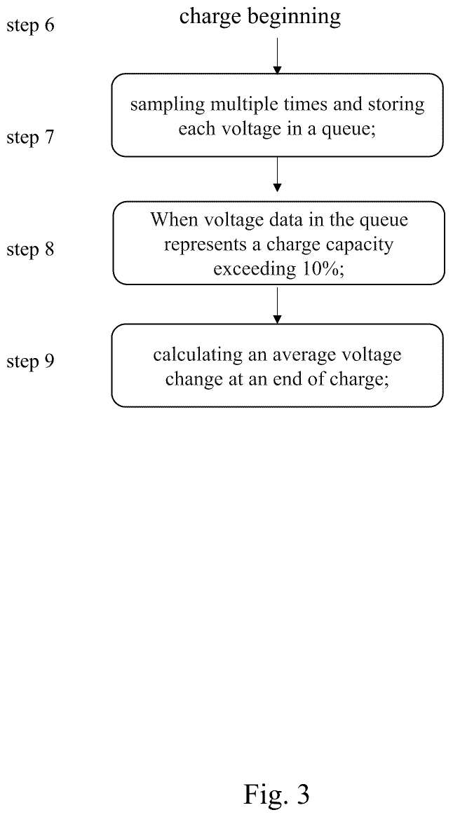

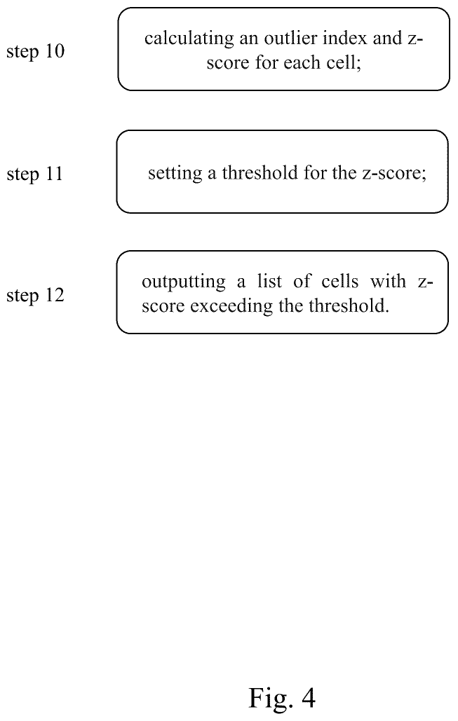

In the following paragraphs, FIG. 2 will explain the calculation of the average voltage change at the beginning of discharge Vx for each cell, FIG. 3 will explain the calculation of the average voltage change at the end of the charge Vy for each cell, and FIG. 4 will explain the calculation of the outlier index and z-score for each cell.

The reference voltage V0 according to the present invention refers to a last voltage when the current is 0A before starting of discharge. Generally, it is a voltage when a cell is fully charged and not yet discharged, and which is a voltage of the cell at float charging or standing.

Calculation of the average voltage change at the initial stage of discharge Vx: after the discharge starts, the voltage is sampled n times successively until 5% of the capacity is discharged off. Each sampled voltage Vi is compared with the reference voltage V0, that is, the reference voltage V0 subtracts the sampled voltage to get voltage difference, then add the voltage differences, and divided by a number of samplings to get an average voltage change at the initial stage of discharge.

Calculation of the average voltage change at the initial stage of discharge

Vx:Vx=(Σᵢ₌₁ⁿ(V0−Vi))/n

wherein

V₀ is a reference voltage; Vi is a sampling voltage; n is a number of samplings.

Float charging means that the charger continuously charges the fully charged battery with a fixed voltage and maintains its state. At this time, the charging current will be slightly greater than 0A.

Standing means: no current is applied to charge or discharge the cell.

A z-score is a statistical measure used to calculate how many standard deviations a value differs from the mean. For an example, the threshold can be set as z-score>3-6.

In an embodiment according to the present invention, we tested a series-connected 160 cells, usually z-score>6 can be used as a threshold. For convenience of explanation, we pick out the data of 16 cells, as shown in Table 1, to illustrate the spirit of this case. When the number of cells is small, the mean and standard deviation will change and hence the z-score is adjusted to be z-score>3 as the threshold, then we found cell 1 must be filtered out for its z-score>3, and the remaining cells are considered normal cells with z-score<3, which function consistent with the overall performance.

a standard deviation σ is calculated as:

$$σ = \sqrt{\frac{\sum {( x - {x}^{-} )}^{2}}{{N}_{c}}} ;$$

calculating z-score for each cell:

$$z - score = \frac{x - {x}^{-}}{σ} ,$$

wherein

x is an outlier index; x-bar is a mean for x; and Nc is a number of cells;

TABLE 1
The data of 16 cells are selected to illustrate the spirit of this invention

| | average | | | |
|---|---|---|---|---|
| | voltage | average | | |
| | change at | voltage | | |
| | initial stage | change at | | |
| | of | end of | Outlier Index | |
| Cell | discharge | charging | x = | |
| no. | (Vx) | (Vy) | (Vx + Vy)/2 | z-score |
| 1 | 409.5444444 | 89.53846154 | 249.541453 | 3.724441209 |
| 2 | 363.1833333 | 6.230769231 | 184.7070513 | 0.276102884 |
| 3 | 347.3055556 | 5.307692308 | 176.3066239 | −0.17068948 |
| 4 | 351.4888889 | 5.076923077 | 178.282906 | −0.065577241 |
| 5 | 345.7055556 | 4.384615385 | 175.0450855 | −0.237786751 |
| 6 | 332.2388889 | 4.230769231 | 168.2348291 | −0.600002913 |
| 7 | 343.5166667 | 3.615384615 | 173.5660256 | −0.316453301 |
| 8 | 341.2277778 | 2.923076923 | 172.0754274 | −0.395733545 |
| 9 | 355.2777778 | 5 | 180.1388889 | 0.033136665 |
| 10 | 352.0277778 | 5.615384615 | 178.8215812 | −0.036926797 |
| 11 | 361.9444444 | 5.461538462 | 183.7029915 | 0.222700093 |
| 12 | 339.6277778 | 5 | 172.3138889 | −0.383050524 |
| 13 | 338.7444444 | 4.461538462 | 171.6029915 | −0.420860928 |
| 14 | 324.9444444 | 5.230769231 | 165.0876068 | −0.767393785 |
| 15 | 336.95 | 3.307692308 | 170.1288462 | −0.499266089 |
| 16 | 342.4722222 | 2.923076923 | 172.6976496 | −0.362639498 |
| | | Mean for x | 179.5158654 | |
| | | Standard | 18.80163592 | |
| | | deviation (σ) | | |

Table 1 shows data of cell 1: the average voltage change at the initial stage of discharge Vx is 409.54 . . . ; the average voltage change at the end of charging Vy is 89.53 . . . ; the outlier index is x=(409.54+89.53)/2=249.54 . . . ; the z-score is z=(249.54-179.51)/18.80=3.72 . . . .

The data for the other cells are expressed in a similar way, please refer to Table 1. In table 1, an average of the outlier indexes is 179.51 . . . and a standard deviation for the outlier index is 18.80 . . . . Assuming that z>3 is used as a threshold for a screen, then cell 1 with z>3 is considered as an outlier cell, and z<3 for the other cells are considered as Normal cells.

### FIG. 2 Shows a Calculation of the Average Voltage Change at the Initial Stage of Discharge According to the Present Invention.

Step 1: discharge beginning; it is deemed that the discharge begins when a discharge current of the series-connected cells is greater than a pre-determined current (ampere) threshold. When 160 cells are connected in series as an example, we set the current lower limit of the series-connected cells to 20A, that is, discharge is deemed starting when a discharge current of the series-connected cells is greater than 20A. The current lower limit can be adjusted according to a different situation.

step 2: sampling multiple times and calculating each voltage difference (V₀-Vᵢ) at the moment of sampling; that is, a reference voltage V₀ minus a voltage Vᵢ at the moment of sampling.

Step 3: summing up the voltage differences

Σᵢ₌₁ⁿ(V₀−Vᵢ);

that is, to sum up the voltage differences for all the previous samples;

Step 4: stopping when the discharge exceeding 5% capacity off; and

Step 5: calculating an average voltage change at an initial stage of discharge Vx; that is, the sum of the voltage differences divided by a number of samples

$$Vx = ( \frac{( {\sum }_{i = 1}^{n} ( V 0 - Vi ) )}{n} ) ;$$

wherein

the reference voltage V₀ is the last voltage for a fully charged cell and when a discharge current is 0 ampere; Vᵢ is a sampling voltage; n is a number of samplings.

When the discharge curve of the lithium-ion cells enters a platform area, the voltage change is small. Therefore, only the change in an early stage of discharge is adopted for calculation in this invention. The early stage is defined 5% of the rated capacity in the invention as an example, the 5% is picked for example only and can be adjusted as necessary.

### FIG. 3 Shows a Calculation of the Average Voltage Change at the End of Charge According to the Present Invention.

step 6: charge beginning;

Step 7: sampling multiple times and storing each voltage in a queue;

Step 8: when the voltage data in the queue represents a charge capacity exceeding 10%; and

Step 9: calculating an average voltage change at an end of charge Vy; that is, to calculate a voltage difference between a sampled voltage and the first voltage in the queue for all sampled voltages, summing up the voltage differences, dividing the sum by a number of samples.

FIG. 4 Shows a Calculation of Outlier Index and z-Score for Each Cell According to the Present Invention.

calculating outlier index x:

[x=(Vx*k1+Vy*k2)/2];

wherein

k1 and k2 are adjustment coefficients which can be adjusted as needed. In the above example k1=1 and k2=1 are used for a calculation as an example only;

a standard deviation σ is calculated as:

$$σ = \sqrt{\frac{\sum {( x - {x}^{-} )}^{2}}{{N}_{c}}} ;$$

calculating z-score for each cell: z=,

$$z = \frac{x - {x}^{-}}{σ} ,$$

wherein

x is an outlier index; x-bar is a mean for x; and Nc is a number of cells;

Step 11: setting a threshold for the z-score; and

Step 12: outputting a list of cells with z-score exceeding the threshold.

The parameters used in the foregoing description are only examples to facilitate readers to understand the spirit of this case, and are not intended to limit the scope of rights for the invention.

Several embodiments have been described by way of examples; it will be apparent to those skilled in the art that various modifications may be configured without departing from the spirit of the present invention. Such modifications are all intended to be covered within the scope of the present invention and as defined by the appended claims.

What is claimed is:

1. An outlier diagnosis method for series-connected sells, comprises the following steps:
Step A: calculating an average voltage change at an initial stage of discharge Vx for a cell;
Step B: calculating an average voltage change at an end of charge Vy for the cell;
Step C: calculating an outlier index and z-score for the cell;
Step D: setting a threshold for the z-score; and
Step E: outputting a list of cells exceeding the threshold.

2. The outlier diagnosis method as claimed in claim 1, wherein
calculating an average voltage change in the initial stage of discharge Vx described in step A, further comprises:
step 1: discharge beginning; when a discharge current of the series-connected cells is greater than a pre-determined current (ampere) threshold;
step 2: sampling multiple times and calculating each voltage difference (V₀-Vᵢ) at the moment of sampling;
Step 3: summing up the voltage differences;
Step 4: stopping when the discharge exceeding P1% capacity off; and
Step 5: calculating an average voltage change at an initial stage of discharge Vx.

3. The outlier diagnosis method as claimed in claim 2, wherein the P1% as described in step 4 is 3%-7%.

4. The outlier diagnosis method as claimed in claim 1, wherein
the calculating an average voltage change at the end of charging Vy for a cell as described in step B, further comprises:
step 6: charge beginning;
Step 7: sampling multiple times and storing each voltage in a queue;
Step 8: when the voltage data in the queue represents a charge capacity exceeding P2%; and
Step 9: calculating an average voltage change at an end of charge Vx.

5. The outlier diagnosis method as claimed in claim 4, wherein the P2% as described in step 8 is 7%-13%.

6. The outlier diagnosis method as claimed in claim 1, wherein
the calculating an outlier index and z-score for each cell as described in step C, further comprises:
step 10: calculating an outlier index and z-score for each cell;
calculating outlier index:
x=(Vx*k1+Vy*k2)/2;
wherein
k1 and k2 are adjustment coefficients; and
calculating z-score for each cell:
z=x−x⁻/σ
wherein
x is an outlier index; x-bar is a mean for x.
Step 11: setting a threshold for the z-score; and
Step 12: outputting a list of cells with z-score exceeding the threshold.
